(19) United States
(12) Patent Application Publication
(10) Pub. No.: US 2023/0156935 A1
(43) Pub. Date: May 18, 2023

(54) IN-VEHICLE ELECTRICAL COMPONENT CIRCUIT UNIT

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Hiroshi SHIMIZU, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/916,958

(22) PCT Filed: Mar. 31, 2021
(86) PCT No.: PCT/JP2021/013805

§ 371 Date: Oct. 4, 2022

(30) Foreign Application Priority Data
Apr. 15, 2020 (JP) 2020-073037

(51) Int. Cl. H05K 5/02; H05K 5/03; B60R 16/02

(52) U.S. Cl. CPC H05K 5/0217; B60R 16/02; H05K 5/03; H05K 5/0247

(57) ABSTRACT

An in-vehicle electrical component circuit unit : includes an electrically insulative holding body configured to hold a circuit member ;a plate wall portion configured to cover a casing through hole provided in an in-vehicle electrical component ; a connector including a connection member that is held by the plate wall portion ; and a sealing member (126) that is provided on a first surface , which is a surface of the plate wall portion that is to be attached to the casing (132), and is configured to come into contact with a peripheral edge of the casing through hole , wherein a portion of the connection member that protrudes on a first surface side includes a circuit-side connection portion (120), the circuit-side connection portion is detachably connectable to the circuit member , and the circuit-side connection portion is inserted into the casing through hole from outside the casing and connected to the circuit member

### TECHNICAL FIELD

The present disclosure relates to an in-vehicle electrical component circuit unit that is housed in a casing of an in-vehicle electrical component.

### BACKGROUND ART

Patent Document 1 discloses a structure in which a circuit unit such as a junction box or the like and a battery module, a battery control system, or the like are housed in a casing of a battery pack that is an in-vehicle electrical component for installation in a vehicle. Here, to enable connection between the circuit unit housed in the casing of the battery pack and an external device, a structure is employed where a connector to which an external partner connector is to be connected is provided on a peripheral wall of the casing, and a coated electrical wire or a bus bar is used to electrically connect the connector and the circuit unit to each other.

### CITATION LIST

### Patent Documents

Patent Document 1: JP 2012-243449A

### SUMMARY OF INVENTION

### Technical Problem

In the structure disclosed in Patent Document 1, the connector is provided on the casing, which gives rise to the issue of the structure of the casing of the in-vehicle electrical component being complex. There is also the latent issue of shifting in the connection position between the connector provided on the casing and the circuit unit housed in the casing being likely to increase due to incremental increases in tolerance including surrounding components. Thus, the coated electrical wire needs to have a certain length in order to absorb the tolerance.

Therefore, disclosed herein is an in-vehicle electrical component circuit unit with a novel structure that enables simplifying the structure of a casing for an in-vehicle electrical component and reducing positional shifting caused by tolerance of the connection position between a connector and a circuit unit.

### Solution to Problem

An in-vehicle electrical component circuit unit according to the present disclosure is an in-vehicle electrical component circuit unit including: an electrically insulative holding body configured to hold a circuit member; a plate wall portion configured to cover a casing through hole provided in a casing of an in-vehicle electrical component; a connector including a connection member that protrudes toward two sides in a plate thickness direction of the plate wall portion while held by the plate wall portion; and an annular sealing member that is provided on a first surface, which is a surface of the plate wall portion that is to be attached to the casing, and is configured to come into contact with a peripheral edge of the casing through hole, wherein a portion of the connection member that protrudes on a first surface side corresponding to the first surface of the plate wall portion includes a circuit-side connection portion, the circuit-side connection portion is detachably connectable to the circuit member, and the circuit-side connection portion of the connection member is inserted into the casing through hole from outside the casing and connected to the circuit member, and the sealing member of the wall plate portion comes into contact with the peripheral edge of the casing through hole from outside of the casing.

### Advantageous Effects of Invention

With the present disclosure, it is possible to provide an in-vehicle electrical component circuit unit that can simplify the casing of the in-vehicle electrical component and reduce positional shift caused by tolerance of the connection position between a connector and a circuit unit.

### BRIEF DESCRIPTION OF DRAWINGS

FIG. 1 is a perspective view showing an in-vehicle electrical component circuit unit according to Embodiment 1.

FIG. 2 is an exploded perspective view showing the in-vehicle electrical component circuit unit shown in FIG. 1.

FIG. 3 is a perspective view of an in-vehicle electrical component including the in-vehicle electrical component circuit unit shown in FIG. 1.

FIG. 4 is an exploded perspective view of the in-vehicle electrical component shown in FIG. 3.

FIG. 5 is an exploded perspective view of the in-vehicle electrical component shown in FIG. 3 as seen from another direction.

FIG. 6 is a transverse cross-sectional view of the in-vehicle electrical component in which main portions of a cross section taken along line VI-VI in FIG. 3 are enlarged.

FIG. 7 is a vertical cross-sectional view of a connector included in the in-vehicle electrical component circuit unit shown in FIG. 1, and corresponds to a cross section taken along line VII-VII in FIG. 1.

FIG. 8 is a plan view of a connector included in an in-vehicle electrical component circuit unit according to another embodiment.

### DESCRIPTION OF EMBODIMENTS

### Description of Embodiments of Present Disclosure

First, embodiments of the present disclosure will be listed and described below.

An in-vehicle electrical component circuit unit of the present disclosure is

an in-vehicle electrical component circuit unit according to the present disclosure is an in-vehicle electrical component circuit unit including: an electrically insulative holding body configured to hold a circuit member; a plate wall portion configured to cover a casing through hole provided in a casing of an in-vehicle electrical component; a connector including a connection member that protrudes toward two sides in a plate thickness direction of the plate wall portion while held by the plate wall portion; and an annular sealing member that is provided on a first surface, which is a surface of the plate wall portion that is to be attached to the casing, and is configured to come into contact with a peripheral edge of the casing through hole, wherein a portion of the connection member that protrudes on a first surface side corresponding to the first surface of the plate wall portion includes a circuit-side connection portion, the circuit-side connection portion is detachably connectable to the circuit member, and the circuit-side connection portion of the connection member is inserted into the casing through hole from outside the casing and connected to the circuit member, and the sealing member of the wall plate portion comes into contact with the peripheral edge of the casing through hole from outside of the casing.

With the in-vehicle electrical component circuit unit of the present disclosure, the connector is provided in the plate wall portion that covers the casing through hole provided in the casing, and the circuit-side connection portion of the connection member of the connector that protrudes toward the first surface side of the plate wall portion can be detachably connected to the circuit member. Thus, the connector can be a constituent element on the in-vehicle electrical component circuit unit side, and the structure of the casing can be simplified. Furthermore, the annular sealing member that comes into contact with the peripheral edge of the casing through hole is provided on the first surface of the plate wall portion, and the circuit-side connection portion of the connection member of the connector held by the plate wall portion is inserted into the casing through hole from outside the casing, and connected directly to the circuit member housed in the casing. Thus, compared to a conventional structure, incremental increases in tolerance can be reduced. In addition, the sealing member of the plate wall portion comes into contact with the peripheral edge of the casing through hole from the outside of the casing. The annular sealing member constitutes a so-called surface seal that is sandwiched between opposing surfaces between the peripheral edge of the casing through hole and the plate wall portion. Thus, it is possible to maintain the water-proofness of the casing through hole, while also absorbing tolerance of the connection position between the connector and the circuit unit in two directions that are orthogonal to the direction in which the plate wall portion is attached to the casing using elastic deformation of the sealing member. As a result, positional shifting caused by tolerance of the connection position between the connector and the circuit unit can be reduced.

Note that the connection member of the connector may be a coated electrical wire that includes a circuit-side connection portion at one end thereof, or a bus bar in which a circuit-side connection portion is integrated with one end portion thereof.

(2) It is preferable that the connection member of the connector is constituted by a bus bar, the circuit-side connection portion is provided at a protruding end portion on the first surface side of the plate wall portion, and an external connection portion is provided at a protruding end portion of the plate wall portion on a second surface side corresponding to a second surface of the plate wall portion that is opposite to the first surface. With the in-vehicle electrical component circuit unit of the present disclosure, positional shifting caused by tolerance of the connection position between the connector and the circuit unit can be reduced, and thus the connection member of the connector can also be employed for a bus bar in place of a conventional coated electrical wire. As a result, the length of the connection member can be reduced, and the casing and the circuit unit can be brought closer to each other, which contribute to a reduction in the size of the in-vehicle electrical component.

(3) It is preferable that the connector includes a hood portion that is provided on the second surface of the plate wall portion and protrudes toward the second surface side while surrounding the external connection portion. The connector includes the hood portion that protrudes toward the second surface side of the plate wall portion, and the external connection portion is disposed inside the hood portion, and thus a connector that can be stably connected to an external partner connector can be provided on the plate wall portion.

(4) It is preferable that the circuit-side connection portion is configured to be bolted to the connection member, and a bolt insertion hole provided in the circuit-side connection portion has an elongated shape that is elongated in a direction in which the plate wall portion is attached to the casing. Bolting allows the circuit-side connection portion to be detachably attached to the circuit member, and thus the connection between the connector and the circuit unit can be kept stable. Furthermore, the bolt insertion hole provided in the circuit-side connection portion includes an elongated hole that is elongated in the direction in which the plate wall portion is attached to the casing. Thus, in addition to the two directions orthogonal to the direction in which the plate wall portion is attached to the casing, the sealing member can also absorb tolerance of the connection position between the connector and the circuit unit in the direction in which the plate wall portion is attached to the casing.

(5) It is preferable that the in-vehicle electrical component circuit unit further includes a base plate portion configured to be placed onto and fixed to the holding body, wherein the base plate portion is made of a material with higher heat conductivity than the holding body. The base plate portion is made of a material that has higher heat conductivity than the holding body, and thus heat transferred to the holding body via the base plate portion can be dissipated from the circuit member including heat generating components such as a relay and a fuse.

(6) It is preferable that the base plate portion is provided with a support leg portion that protrudes downward from the base plate portion. Due to provision of the support leg portion provided on the base plate portion, the circuit can be placed onto other components housed in the in-vehicle electrical component. Also, changing the protruding length of the leg support portion makes for easy adjustment of the height position of the plate wall portion relative to the casing through hole, and a highly universal in-vehicle electrical component circuit unit that is applicable to casing through holes provided at various height positions can be provided.

### Detailed Description of Embodiment of the Present Disclosure

Specific examples of an in-vehicle electrical component circuit unit of the present disclosure will be described below with reference to the drawings. Note that the present disclosure is not limited to these illustrative examples, but is indicated by the claims, and all changes that come within the meaning and range of equivalency of the claims are intended to be embraced therein.

### Embodiment 1

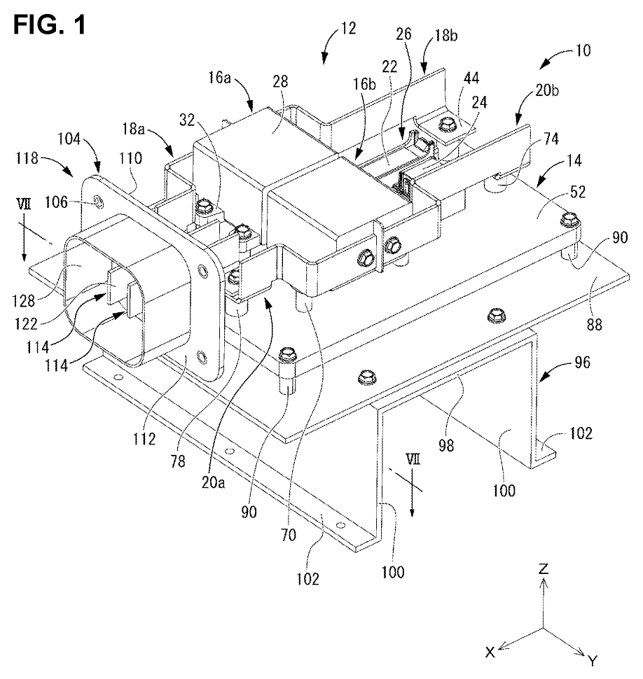

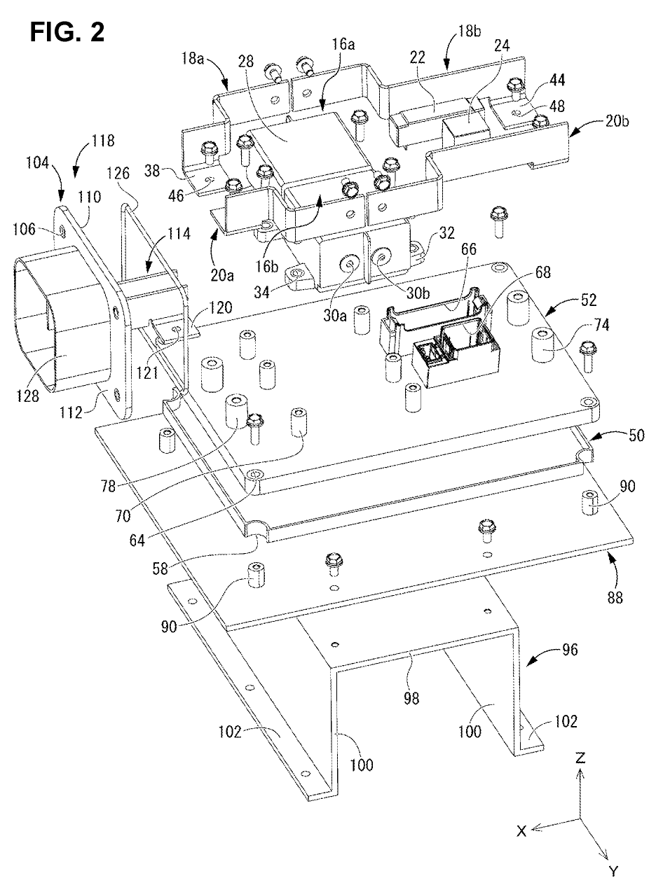

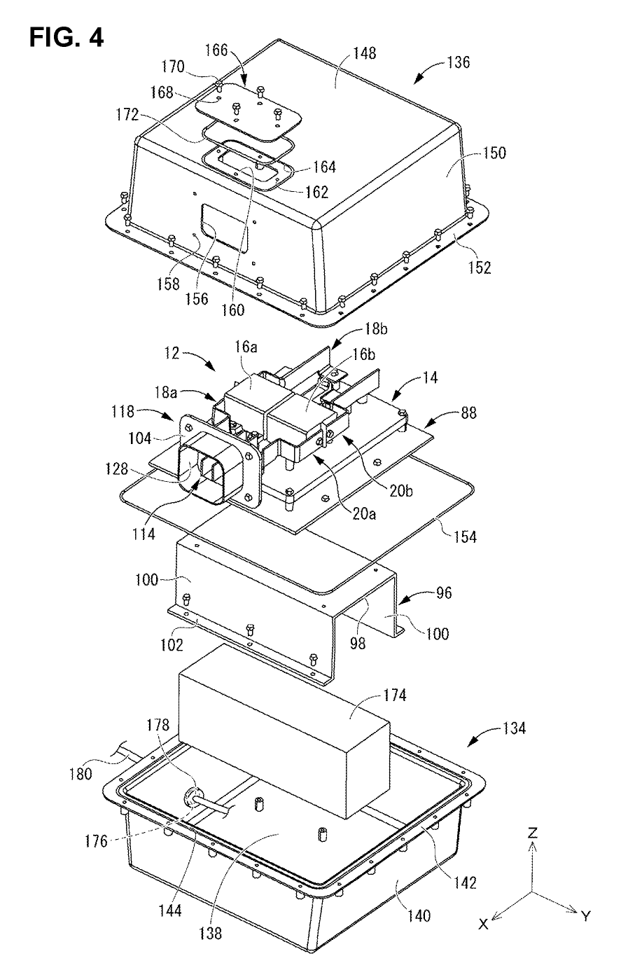

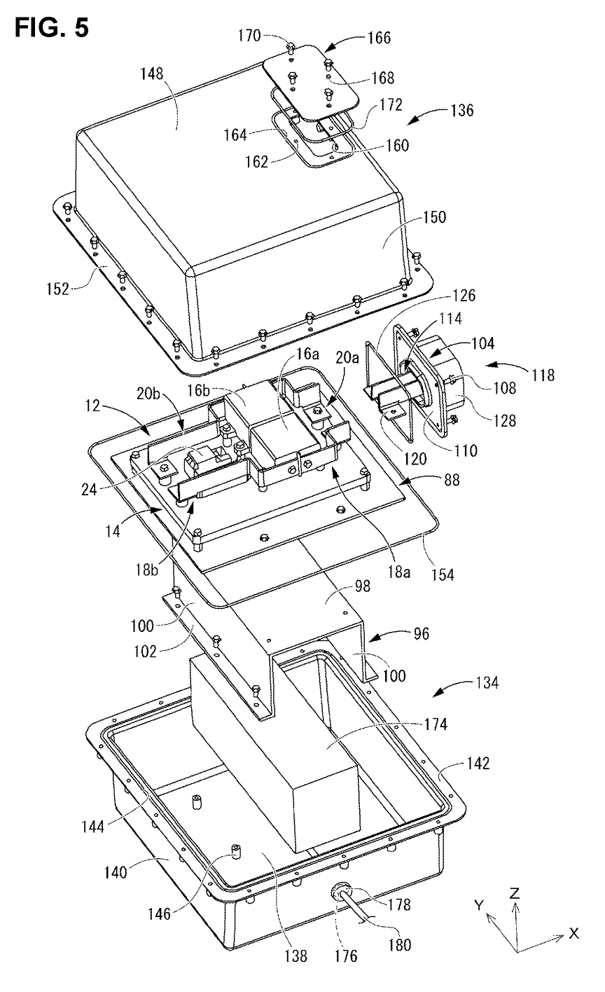

Embodiment 1 of the present disclosure will be described below with reference to FIGS. 1 to 7. An in-vehicle electrical component circuit unit 10 is for installation in a vehicle such as an electric car or a hybrid car (not shown), and supplies power from a power source such as a battery (not shown) to a load such as a motor (not shown), and performs control of such power supply. Note that the in-vehicle electrical component circuit unit 10 can be positioned in any orientation, but in the following description, the Z direction is the upward direction, the Y direction is the rightward direction, and the X direction is the forward direction. Also, there may be cases where only some members among a plurality of identical members are given reference numerals while reference numerals are omitted for the other members.

### In-Vehicle Electrical Component Circuit Unit 10

The in-vehicle electrical component circuit unit 10 includes a circuit member 12 and an electrically insulative holding body 14 that holds the circuit member 12. Also, the in-vehicle electrical component circuit unit 10 includes a later-described plate wall portion 104, a connector 118, and a sealing member 126.

### Circuit Member 12

In Embodiment 1, the circuit member 12 includes positive electrode-side and negative electrode-side relays 16a and 16b, bus bars 18a and 18b that are electrically connected to the positive electrode-side relay 16a, bus bars 20a and 20b that are electrically connected to the negative electrode-side relay 16b, a pre-charge resistor 22, and a pre-charge relay 24. The pre-charge resistor 22 and the pre-charge relay 24 are electrically connected to either the positive electrode-side or the negative-electrode side relay (for example, the positive electrode-side relay 16a) to form a pre-charge circuit 26. Note that an unshown pre-charge resistor and pre-charge relay may also be electrically connected to the other relay (for example, the negative electrode-side relay 16b) to form a pre-charge circuit.

The positive electrode-side and negative electrode-side relays 16a and 16b are provided facing away from each other. In Embodiment 1, the positive electrode-side and negative electrode-side relays 16a and 16b each face outward in the left-right direction. The relays 16a and 16b each include a relay main body 28 that has a hollow parallelopiped shape. Each outer end surface in the left-right direction of the relays 16a and 16b serving as the front surface thereof is provided with a pair of connection portions 30a and 30b in the form of through holes that extend through the corresponding relay main body 28 in the thickness direction thereof, and that are formed spaced apart from each other in the front-rear direction. Also, each relay main body 28 is provided with leg portions 32 that protrude outward in the front-rear direction. Each leg portion 32 is provided with a bolt insertion hole 34 extending therethrough in the up-down direction.

Note that the relays 16a and 16b and the pre-charge relay 24 are relays in which a contact portion is switched ON/OFF by moving the contact portion with use of the conductive state of an exciting coil. The relays 16a and 16b and the pre-charge relay 24 are turned ON/OFF by a control circuit in a wiring component 174 provided in a later-described in-vehicle electrical component 130.

The bus bars 18a and 20a are electrically connected to the front connection portions 30a of the relays 16a and 16b, respectively, and extend forward. The bus bars 18b and 20b are electrically connected to the rear connection portions 30b of the relays 16a and 16b, respectively, and extend rearward.

The bus bars 18a, 18b, 20a, and 20b are each formed by a metal plate member that has conductive properties, and are formed by folding the metal plate member into a predetermined shape through pressing or the like. The front end portions of the front bus bars 18a and 20a are folded inward in the left-right direction so as to approach each other, and front connection portions 38 are respectively formed by the folded portions. Also, the rear end portions of the rear bus bars 18b and 20b are folded inward in the left-right direction so as to approach each other, and rear connection portions 44 are respectively formed by the folded portions. Note that the front connection portions 38 and the rear connection portions 44 are respectively provided with bolt insertion holes 46 and bolt insertion holes 48 that extend therethrough in the thickness direction (up-down direction). Specifically, in Embodiment 1, the bolt insertion holes 46 and 48 each have a substantially perfect circle shape.

By bolting the rear end portions of the front bus bars 18a and 20a and the connection portions 30a of the relays 16a and 16b to each other, the relays 16a and 16b and the bus bars 18a and 20a are electrically connected to each other. Also, by bolting the front end portions of the rear bus bars 18b and 20b and the connection portions 30b of the relays 16a and 16b to each other, the relays 16a and 16b and the bus bars 18b and 20b are electrically connected to each other.

### Holding Body 14

In Embodiment 1, the holding member 14 for holding the circuit member 12 has a substantially hollow box shape. Specifically, in Embodiment 1, the holding body 14 includes a lower case 50 that is open upward and an upper case 52 that is open downward. Note that the holding body 14 may house un-shown bus bars that connect the relays 16a and 16b and the pre-charge circuit 26, an un-shown bus bar or the like for connection inside the pre-charge circuit 26, or the like. The upper and lower cases 50 and 52 may be made of a hard synthetic resin, for example.

The lower case 50 has a substantially rectangular box shape overall. In Embodiment 1, the four corners of the lower case 50 are each provided with a notch-shaped recess 58.

The upper case 52 has a substantially rectangular box shape overall. In Embodiment 1, the four corners of the upper case 52 are each provided with a bolt insertion hole 64 that extends therethrough in the up-down direction. Also, the rear portion of the upper case 52 is provided with a pre-charge resistor mounting portion 66 and a pre-charge relay mounting portion 68 that are open upward and are for respectively housing the pre-charge resistor 22 and the pre-charge relay 24.

The aforementioned holding body 14 is formed by placing the upper case 52 onto the lower case 50 and fixing the upper case 52 to the lower case 50. Note that the fixing structure between the lower case 50 and the upper case 52 is not limited, and a fixing structure realized by press-fitting, recession/projection fitting, or the like may be employed.

Furthermore, substantially tubular relay fixing portions 70 that protrude upward are provided on the upper case 52 at positions corresponding to the leg portions 32 of the relays 16a and 16b. Also, substantially tubular rear bus bar fixing portions 74 that protrude upward are provided on the rear end portion of the upper case 52 at positions that correspond to the rear connection portions 44 of the rear bus bars 18b and 20b. Furthermore, substantially tubular front bus bar fixing portions 78 that protrude upward are provided on the front end portion of the upper case 52 at positions that correspond to the front side connection portions 38 of the front bus bars 18a and 20a.

By bolting the leg portions 32 of the relays 16a and 16b and the relay fixing portions 70 to each other, the relays 16a and 16b are held by the holding body 14. Also, by bolting the rear connection portions 44 and the rear bus bar fixing portions 74 to each other, the rear bus bars 18b and 20b are held by the holding body 14. At this time, terminal portions (not shown) provided at an end portion of a later-described wire harness 180 are overlaid onto the rear connection portions 44 of the bus bars 18b and 20b, and fastened thereto using bolts. Thus, the rear bus bars 18b and 20b and the wire harness 180 are electrically connected to each other. Furthermore, by bolting the front connection portions 38 and the front bus bar fixing portions 78 to each other, the front bus bars 18a and 20a are held by the holding body 14. At this time, circuit-side connection portions 120 of the later-described connector 118 are respectively overlaid onto the front connection portions 38 of the bus bars 18a and 20a, and fastened thereto using bolts. Accordingly, the front bus bars 18a and 20a and the connector 118 are electrically connected to each other.

### Base Plate Portion 88

As previously described, the holding body 14 is placed onto and fixed to a base plate portion 88. The base plate portion 88 has a substantially rectangular plate shape overall. The base plate portion 88 is preferably made of a material with higher heat conductivity than the holding body 14, and is made of a metal such as aluminum, an aluminum alloy, or the like.

In Embodiment 1, the four corners of the base plate portion 88 are each provided with a substantially tubular holding body fixing portion 90 that protrudes upward. By placing the holding body 14 onto the holding body fixing portions 90 and bolting them to each other, the holding body 14 and the base plate portion 88 are fixed to each other.

### Support Leg Portion 96

The base portion 88 is provided with a support leg portion 96 that protrudes downward (direction opposite to Z direction arrow). In Embodiment 1, the support leg portion 96 is a substantially gutter-shaped member that extends in the left-right direction. That is, the support leg portion 96 includes a substantially rectangular upper bottom wall 98 that extends in the left-right direction, and a pair of side walls 100 that protrude downward from the front and rear ends of the upper bottom wall 98. Also, the lower ends of the side walls 100 are each provided with a flange-shaped portion 102 that protrudes outward in the front-rear direction. The support leg portion 96 may be made of metal or a hard synthetic resin, for example.

By bolting the central portion of the base plate portion 88 in the front-rear direction and the upper bottom wall 98 of the support leg portion 96 to each other, the base plate portion 88 and the support leg portion 96 are fixed to each other.

### Plate Wall Portion 104 and Connector 118

A casing through-hole 156 provided on the front side of a later-described casing 132 is configured such that it can be covered by the substantially rectangular plate wall portion 104. In other words, the plate wall portion 104 is greater in size than the casing through-hole 156. The plate wall portion 104 is provided with bolt insertion holes 106 that extend therethrough in the thickness direction thereof (front-rear direction) at positions that correspond to bolt holes 158 provided around the casing through-hole 156.

The plate wall portion 104 is overlaid onto the casing 132 (upper cover 136) from the outside and attached thereto. Accordingly, the rear end surface of the plate wall portion 104 is a first surface 110 that is overlaid onto and attached to the casing 132. Also, the front end surface of the plate wall portion 104 on the side opposite to the first surface 110 is a second surface 112.

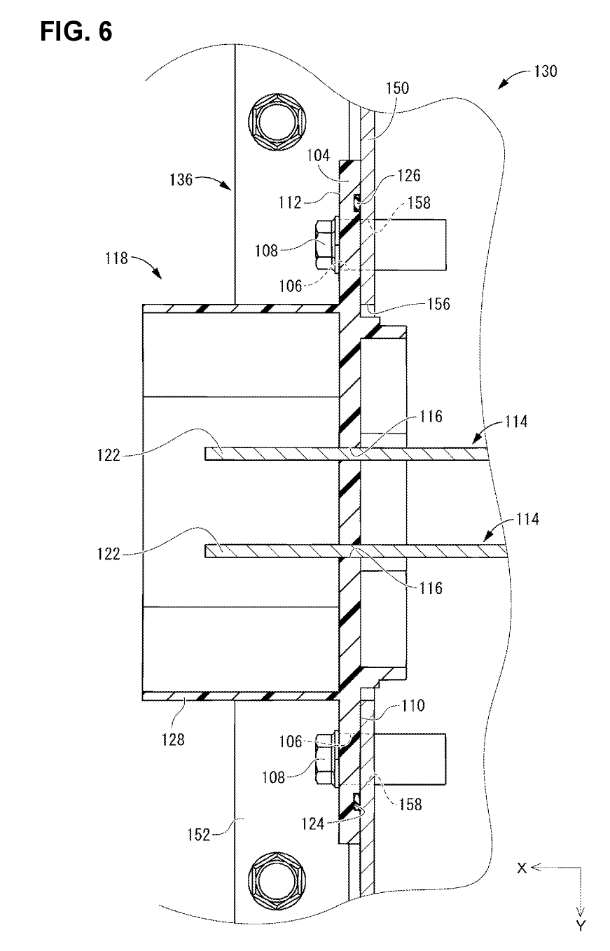

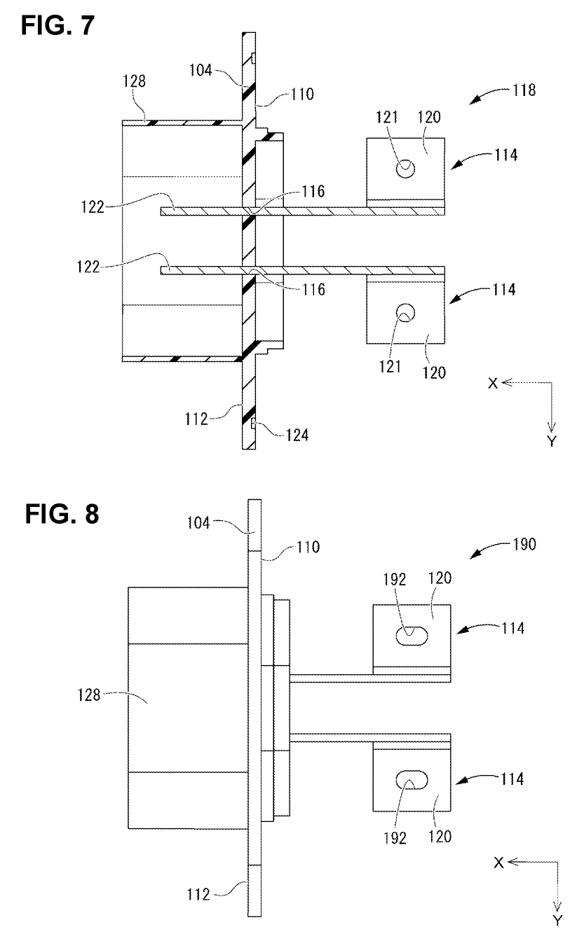

Furthermore, the plate wall portion 104 includes a connection member 114 that protrudes toward both sides in the thickness direction (the first surface 110 side and the second surface 112 side). In Embodiment 1, a pair of connection members 114 that are spaced apart from one another in the left-right direction are provided. Specifically, as shown in FIGS. 6 and 7, the plate wall portion 104 is provided with a pair of through holes 116 that are substantially rectangular and are distanced from one another in the left-right direction. By press-fitting the connection members 114 into the through holes 116, the connection members 114 are held by the plate wall portion 104. Thus, a connector 118 including the plate wall portion 104 and the connection members 114 is configured.

Each connection member 114 is formed by a bus bar made of a conductive metal. Specifically, each connection member 114 is formed by bending, for example, a metal plate member through pressing or the like. In Embodiment 1, the rear end portion of each connection member 114 is folded outward in the direction in which the connection members 114 oppose each other (outward in the left-right direction) so as to extend horizontally. The rear end portions of the connection members 114, that is, the protruding end portions on the first surface side 110 (rear side) of the plate wall portion 104, respectively form the circuit-side connection portions 120. Each circuit-side connection portion 120 is provided with an insertion hole 121 that extends therethrough in the thickness direction (up-down direction) thereof. Specifically, in Embodiment 1, as also shown in FIG. 7, the bolt insertion holes 121 are substantially perfectly circular in shape. Also, the front end portions of the connection members 114, that is, the protruding end portions on the second surface 112 side, form external connection portions 122.

The circuit-side connection portions 120 are overlaid onto the front connection portions 38 at the front ends of the front bus bars 18a and 20a when the plate wall portion 104 is fixed to the casing 132 (upper cover 136). By inserting bolts into the bolt insertion holes 46 of the front connection portions 38 and the bolt insertion holes 121 of the circuit-side connection portions 120 and fastening the front connection portions 38 and the circuit-side connection portions 120 to each other, the front bus bars 18a and 20a and the connection members 114 are electrically connected to each other. Accordingly, in Embodiment 1, the in-vehicle electrical component circuit unit 10 includes the plate wall portion 104 and the connector 118. Also, by unscrewing the bolts, the front connection portions 38 and the circuit-side connection portions 120 are disconnected, and thus the front connection portions 38 (circuit member 12) and the circuit-side connection portions 120 can be detachably connected to each other.

Furthermore, as also shown in FIG. 6, the outer peripheral portion of the first surface 110 that is the rear end surface of the plate wall portion 104 is provided with a substantially annular groove 124 that is open rearward. An annular sealing member 126 that is made of rubber, an elastomer, or the like is provided in the groove 124. Specifically, by overlaying the plate wall portion 104 onto the casing 132 (surrounding edge of later-described casing through-hole 156) and fixing the plate wall portion 104 thereto, the sealing member 126 is compressed from both the front and back between the plate wall portion 104 and the casing 132, and thus the space between the casing 132 (casing through hole 156) and the plate wall portion 104 is sealed in a liquid-tight manner.

Furthermore, in Embodiment 1, the second surface side 112 (front side) of the plate wall portion 104 is provided with a hood 128 that protrudes on the second surface 112 side (front side) while surrounding the connection members 114 on the outer peripheral side of the connection members 114. Specifically, in Embodiment 1, the hood 128 protrudes forward beyond the external connection portions 122, which are the front end portions of the connection members 114.

### In-Vehicle Electrical Component 130

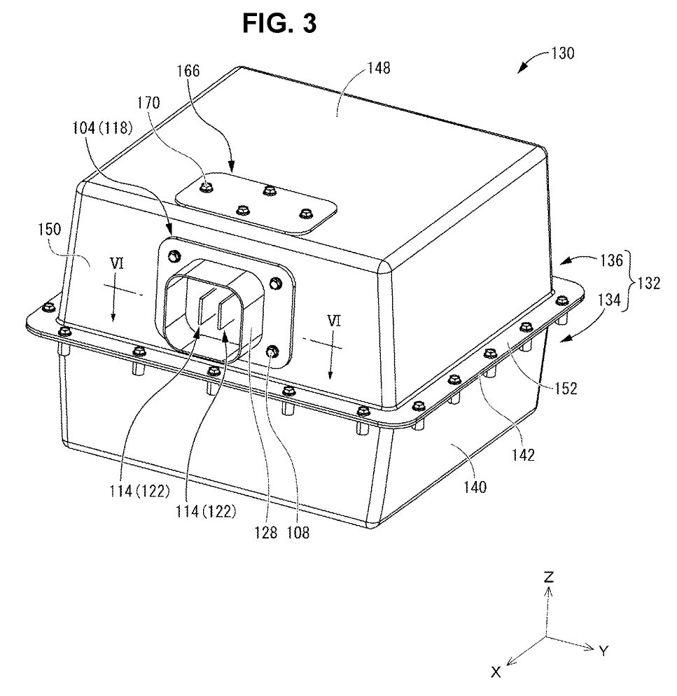

As previously described, the in-vehicle electrical component 130 shown in FIG. 3 and the like includes the in-vehicle electrical component circuit unit 10. Specifically, the in-vehicle electrical component circuit unit 10 is housed in the casing 132 of the in-vehicle electrical component 130.

### Casing 132

In Embodiment 1, the casing can be divided in the up-down direction. Specifically, the casing 132 includes a lower cover 134 that is open upward and an upper cover 136 that is open downward. Note that the lower and upper covers 134 and 136 are made of, for example, a metal such as aluminum or an aluminum alloy, a hard synthetic resin, or the like.

The lower cover 134 has a substantially rectangular box shape overall. Specifically, the lower cover 134 includes a substantially rectangular bottom wall 138 and a peripheral wall 140 that protrudes upward from the outer peripheral edge portion of the bottom wall 138. Also, the upper end of the peripheral wall 140 is provided with a substantially annular lower cover flange portion 142 that protrudes circumferentially outward. Furthermore, the lower cover flange portion 142 is provided with an annular groove 144 that is open upward and extends over the entire lower cover flange portion 142 in a circumferential direction thereof.

Furthermore, the bottom wall 138 of the lower cover 134 is provided with substantially tubular support leg fixing portions 146 that protrude upward. By bolting the flange-shaped portions 102 of the support leg portions 96 and the support leg fixing portions 146 to each other, the support leg portions 96 are fixed to the lower cover 134.

The upper cover 136 has a substantially rectangular box shape overall. Specifically, the upper cover 136 includes a substantially rectangular upper bottom wall 148 and a peripheral wall 150 that protrudes downward from the outer peripheral edge portion of the upper bottom wall 148. Also, the bottom end of the peripheral wall 150 is provided with a substantially annular upper cover flange portion 152 that protrudes to the outer peripheral side. Furthermore, by bolting the lower cover flange portion 142 and the upper cover flange portion 152 to each other, the lower cover 134 and the upper cover 136 are fixed to each other.

Note that an annular sealing member 154 that is an elastic body made of rubber, an elastomer, or the like is provided in the groove 144 in the space between overlapping surfaces between the lower cover flange portion 142 and the upper cover flange portion 152. Thus, the sealing member 154 is compressed in the up-down direction between the lower cover flange portion 142 and the upper cover flange portion 152 when the lower cover 134 and the upper cover 136 are fixed to one another, and thus the space between the lower cover 134 and the upper cover 136 is sealed in a liquid-tight manner.

The casing through hole 156 is formed in the front portion of the peripheral wall 150 of the upper cover 136 so as to extend therethrough in the thickness direction thereof (front-rear direction). The casing through hole 156 is substantially rectangular in shape. The bolt holes 158 are provided around the casing through hole 156. Also, a through window 160 is formed in the front portion of the upper bottom wall 148 so as to extend therethrough in the thickness direction thereof (up-down direction). A plurality of bolt holes 162 are provided around the through window 160. Furthermore, an annular groove 164 is formed on the outer peripheral side of the bolt holes 162.

A substantially rectangular cover 166 that is larger in size than the through window 160 is overlaid onto the through window 160 from above and fixed to the peripheral edge portion of the through window 160. Specifically, the cover 166 is provided with bolt insertion holes 168 that extend therethrough in the thickness direction of the cover 166 (up-down direction) at positions that correspond to the bolt holes 162 around the through window 160. By matching the positions of the bolt holes 162 around the through window 160 with the bolt insertion holes 168 of the cover 166 and inserting bolts 170 and fastening the bolts 170, the cover 166 can be fixed to the through window 160 from above the upper cover 136.

Note that an annular sealing member 172 that is an elastic body made of rubber, an elastomer, or the like is provided in the groove 164 between overlapping surfaces between the upper cover 136 and the cover 166. Accordingly, the sealing member 172 is compressed in the up-down direction when the upper cover 136 and the cover 166 are fixed to one another, and thus the space between the upper cover 136 and the cover 166 is sealed in a liquid-tight manner.

Note that, in Embodiment 1, the wiring component 174 is provided in the region covered by the support leg portion 96 and the lower cover 134 inside the casing 132. The wiring component 174 is an electrical component that includes a control circuit or the like. In Embodiment 1, the in-vehicle electrical component 130 includes the wiring component 174.

Specifically, in Embodiment 1, a wire harness insertion hole 176 is formed in a portion of the peripheral wall 140 of the lower cover 134 so as to extend therethrough in the thickness direction of the peripheral wall 140. A substantially cylindrical rubber grommet 178 is fitted into the wire harness insertion hole 176, and the wire harness 180 is inserted into the casing 132 via the through hole provided in the center of the grommet 178. The wire harness 180 is electrically connected to the in-vehicle electrical component circuit unit 10 and the wiring component 174, and supplies power to the in-vehicle electrical component circuit unit 10 and the wiring component 174. Also, the grommet 178 blocks water from entering the casing 132 via the wire harness insertion hole 176.

### Assembly of In-Vehicle Electrical Component Circuit Unit 10 and In-Vehicle Electrical Component 130

Next, a specific example of assembly of the in-vehicle electrical component circuit unit 10 will be described. Note that the assembly of the in-vehicle electrical component circuit unit 10 is not limited to the following.

First, the lower case 50 and the upper case 52 constituting the holding body 14 are prepared. As needed, bus bars for connection of the relays 16a and 16b to the pre-charge circuit 26 and a bus bar for connection inside the pre-charge circuit 26 are housed between the lower case 50 and the upper case 52. Then, the upper case 52 is placed on and fixed to the lower case 50 to form the holding body 14.

Next, the pre-charge resistor 22 and the pre-charge relay 24 are respectively mounted to the pre-charge resistor mounting portion 66 and the pre-charge relay mounting portion 68 provided on the upper surface of the holding body 14. Then, the relays 16a and 16b and the bus bars 18a, 18b, 20a, and 20b are placed on the upper surface of the holding body 14 and fixed with bolts. When fixing the rear connection portions 44, which are the rear end portions of the bus bars 18b and 20b, using bolts, the terminal portions provided at the end portion of the wire harness 180 are overlaid onto and fastened to the rear connection portions 44.

Then, once the base plate portion 88 and the support leg portion 96 have been prepared, the holding body 14 holding the circuit member 12 is placed onto and fixed to the base plate portion 88 using bolts. Next, the base plate portion 88 is overlaid onto the support leg portion 96 and fixed thereto using bolts. Accordingly, the circuit member 12, the holding body 14, the base plate portion 88, and the support leg portion 96 are fixed as a single body. Note that the order in which the relays 16a and 16b, the bus bars 18a, 18b, 20a, and 20b, the pre-charge resistor 22, and the pre-charge relay 24 are fixed in the holding body 14 is not limited. Also, the order in which the circuit member 12, the holding body 14, the base plate portion 88, and the support leg portion 96 are fixed is not limited.

Then, the lower cover 134, the upper cover 136, and the wiring component 174 constituting the casing 132 are prepared. The wiring component 174 connected to the wire harness 180 is placed on the bottom wall 138 of the lower cover 134, and the support leg portion 96 is placed over the wiring component 174 from above and fixed thereto using bolts. Then, the upper cover 136 is placed over the circuit member 12 from above, and the lower cover 134 and the upper cover 136 are fixed to each other using bolts. Thus, the circuit member 12, the holding body 14, the base plate portion 88, the support leg portion 96, and the wiring component 174 are housed in the casing 132.

Next, the connector 118 is prepared. The connector 118 is inserted into the casing through hole 156 from outside the casing 132, and the outer peripheral edge portion of the plate wall portion 104 is overlaid onto the peripheral edge of the casing through hole 156. Then, the positions of the bolt insertion holes 106 of the plate wall portion 104 and the bolt holes 158 around the casing through hole 156 are matched with each other. Next, by inserting bolts 108 into the bolt holes 158 and the bolt insertion holes 106 and fastening them, the plate wall portion 104 is fixedly attached to the casing 132, and the casing through hole 156 is covered by the plate wall portion 104. At this time, the front connection portions 38 of the front bus bars 18a and 20a are overlaid onto the circuit-side connection portions 120 of the connector 118. A jig is inserted through the through window 160 formed on the upper side of the casing 132 to bolt the front connection portions 38 and the circuit-side connection portions 120 to each other. Accordingly, the in-vehicle electrical component circuit unit 10 is complete. Next, by placing the cover 166 onto the upper cover 136 from above and fixing the cover 166 using the bolts 170, the through window 160 is closed off. Thus, the in-vehicle electrical component 130 is complete.

In the in-vehicle electrical component circuit unit 10 with the above-described structure, the circuit-side connection portions 120 of the connector 118 and the front connection portions 38 provided at the front end portions of the circuit member 12 are detachably connected to each other by bolts. Thus, the in-vehicle electrical component circuit unit 10 can include the connector 118. In other words, the in-vehicle electrical component circuit unit 10 of the present disclosure can be applied to the casing 132 including the casing through hole 156, the design freedom of the casing 132 can be increased, and a reduction in the size and simplification of the casing 132 as well as the in-vehicle electrical component 130 can be realized, for example.

Also, as shown in FIG. 6, the annular sealing member 126 made of an elastic material is provided between the plate wall portion 104 and the casing 132 (upper cover 136). Accordingly, water can be blocked from entering between the plate wall portion 104 and the casing 132. Furthermore, the annular sealing member 126 forms a so-called surface seal that is sandwiched between opposing surfaces of the plate wall portion 104 and the casing 132. Thus, the attachment tolerance in two directions (Y and Z directions) that are orthogonal to the direction in which the plate wall portion 104 is attached to the casing 132 is absorbed by elastic deformation of the sealing member 126. Accordingly, connection between the connector 118 and the circuit member 12, specifically, bolting between the circuit-side connection portions 120 and the front connection portions 38 can be more reliably achieved.

Furthermore, as described above, the tolerance between the connector 118 and the circuit member 12 is absorbed by elastic deformation of the sealing member 126. Therefore, with Embodiment 1, the connection members 114 of the connector 118 can be formed using bus bars with less elasticity than a coated electrical wire, for example. Specifically, the aforementioned effect of absorbing tolerance also makes it possible to make the connection members 114 of the connector 118 shorter, for example. Accordingly, the in-vehicle electrical component circuit unit 10 can also be installed closer to the casing through hole 156 of the casing 132, and thus the size of the casing 132 as well as the in-vehicle electrical component 130 can also be reduced.

Also, in Embodiment 1, the hood portion 128 on the second surface 112 (front end surface) side of the plate wall portion 104 surrounds the external connection portions 122 of the connection members 114, and thus the likelihood of unintentional contact with the external connection portions 122 can be reduced. Specifically, in Embodiment 1, the hood 128 protrudes outward (forward) beyond the external connection portions 122, and thus the likelihood of unintentional contact with the external connection portions 122 can be reduced even more.

Furthermore, in Embodiment 1, the base plate portion 88 for placement of the holding body 14 is made of a material with higher heat conductivity than that of the holding body 14, and thus heat generated by the circuit member 12 is transferred to the base plate portion 88 via the holding body 14 and dissipated from the base plate portion 88. Specifically, in Embodiment 1, the holding body 14 has a hollow structure, and the holding body 14 and the base plate portion 88 are arranged with a gap therebetween, and thus heat can be more steadily dissipated from the holding body 14 and the base plate portion 88.

Furthermore, in Embodiment 1, the support leg portion 96 protruding downward from the base plate portion 88 is provided. In other words, by adjusting the height of the support leg portion 96, the height position of the base plate portion 88 as well as the circuit member 12 can also be adjusted, and thus design freedom regarding the shape of the casing 132 can be increased even more. Also, in Embodiment 1, the wiring member 174 can also be positioned below the support leg portion 96. In other words, adjusting the height of the support leg portion 96 makes it possible to avoid contact between the base plate portion 88 (upper bottom wall 98) and the wiring member 174, and also suppress the transfer of heat to the wiring member 174.

### Other Embodiments

The technology described in the present specification is not limited to the embodiments thus described using the above description and drawings, and embodiments such as the following are to be included in the technical scope of the present specification, for example.

(1) FIG. 8 shows a connector 190 included in an in-vehicle electrical component circuit unit according to a different aspect of the present disclosure. Note that, in the in-vehicle electrical component circuit unit of the present aspect, structures other than that of the connector 190 are the same as those in Embodiment 1, and thus a detailed description is omitted. In the present aspect, bolt insertion holes 192 in the circuit-side connection portions 120 have an elongated hole shape (ellipse shape) that is elongated in the front-rear direction, which is the direction in which the plate wall portion 104 is attached to the casing 132. Accordingly, when connecting the connector 190 and the circuit member 12, specifically, when fixing the circuit-side connection portions 120 to the front connection portions 38 using bolts, attachment tolerance in the direction in which the plate wall portion 104 is attached to the casing 132 can be absorbed by the annular sealing member 126 in addition to tolerance in the Y and Z directions. Thus, tolerance between the connector 190 and the circuit member 12 can be more reliably absorbed. Note that, in place of or in addition to the bolt insertion holes 192 in the circuit-side connection portions 120, the bolt insertion holes 46 of the front connection portions 38 may have an elongated hole shape (ellipse shape) that is elongated in the front-rear direction.

(2) In Embodiment 1, an example of the in-vehicle electrical component 130 was described in which the wiring component 174 and the in-vehicle electrical component circuit unit 10 of the present disclosure are housed inside the casing 132, but the present invention is not limited to this. Instead of a wiring component, the in-vehicle electrical component may be a battery pack housing a battery, for example. In this case, there is no need to provide a wire harness or wire harness insertion hole that extend through the casing.

(3) The casing is not limited to any specific shape, provided that a casing through hole is provided. For example, in Embodiment 1, the casing through hole 156 is provided in the upper cover 136, but the casing through hole 156 may be provided in the lower cover. Note that the shapes of the casing through hole and the plate wall portion that covers the casing through hole are not limited to a substantially rectangular shape as described in Embodiment 1, and may have a polygonal shape such as a triangular shape, or a circular shape (including a perfect circle, ellipse, oval, semi-circle, and the like).

(4) In Embodiment 1, the support leg portion 96 is substantially gutter-shaped, and the side walls 100 protrude downward from the front and rear ends of the upper bottom wall 98, but a configuration is possible where side walls protrude downward from the base plate portion, and the side walls form the support leg portion. Also, the support leg portion and the base plate portion may be formed as separate bodies and then fixed to one another as described in Embodiment 1, or formed as one piece. Note that the base plate portion and the support leg portion are not essential to the present disclosure.

(5) In Embodiment 1, the support leg portion 96 is fixed to the bottom wall 138 of the casing 132 (lower cover 134), but the present invention is not limited to this aspect. The support leg portion can be fixed at an appropriate location, such as being fixed to the peripheral wall of the upper cover or the lower cover of the casing.

List of Reference Numerals

| | |
|---|---|
| 10 | In-vehicle electrical component circuit unit |
| 12 | Circuit member |
| 14 | Holding body |
| 16 a | (Positive electrode-side) relay |
| 16 b | (Negative electrode-side) relay |
| 18a, 18b | Bus bar (connected to positive electrode-side relay) |
| 20a, 20b | Bus bar (connected to negative electrode-side relay) |
| 22 | Pre-charge resistor |
| 24 | Pre-charge relay |
| 26 | Pre-charge circuit |
| 28 | Relay main body |
| 30a, 30b | Connection portion |
| 32 | Leg portion |
| 34 | Bolt insertion hole |
| 38 | Front connection portion |
| 44 | Rear connection portion |
| 46, 48 | Bolt insertion hole |
| 50 | Lower case |
| 52 | Upper case |
| 58 | Recess |
| 64 | Bolt insertion hole |
| 66 | Pre-charge resistor mounting portion |
| 68 | Pre-charge relay mounting portion |
| 70 | Relay fixing portion |
| 74 | Rear bus bar fixing portion |
| 78 | Front bus bar fixing portion |
| 88 | Base plate portion |
| 90 | Holding body fixing portion |
| 96 | Support leg portion |
| 98 | Upper bottom wall |
| 100 | Side wall |
| 102 | Flange-shaped portion |
| 104 | Plate wall portion |
| 106 | Bolt insertion hole |
| 108 | Bolt |
| 110 | First surface |
| 112 | Second surface |
| 114 | Connection member |
| 116 | Through hole |
| 118 | Connector |
| 120 | Circuit-side connection portion |
| 121 | Bolt insertion hole |
| 122 | External connection portion |
| 124 | Groove |
| 126 | Sealing member |
| 128 | Hood portion |
| 130 | In-vehicle component |
| 132 | Casing |
| 134 | Lower cover |
| 136 | Upper cover |
| 138 | Bottom wall |
| 140 | Peripheral wall |
| 142 | Lower cover flange portion |
| 144 | Groove |
| 146 | Support leg fixing portion |
| 148 | Upper bottom wall |
| 150 | Peripheral wall |
| 152 | Upper cover flange portion |
| 154 | Sealing member |
| 156 | Casing through hole |
| 158 | Bolt hole |
| 160 | Through window |
| 162 | Bolt hole |
| 164 | Groove |
| 166 | Cover |
| 168 | Bolt insertion hole |
| 170 | Bolt |
| 172 | Sealing member |
| 174 | Wiring component |
| 176 | Wire harness insertion hole |
| 178 | Grommet |
| 180 | Wire harness |
| 190 | Connector |
| 192 | Bolt insertion hole |

1. An in-vehicle electrical component circuit unit comprising:
an electrically insulative holding body configured to hold a circuit member;
a plate wall portion configured to cover a casing through hole provided in a casing of an in-vehicle electrical component;
a connector including a connection member that protrudes toward two sides in a plate thickness direction of the plate wall portion while held by the plate wall portion; and
an annular sealing member that is provided on a first surface, which is a surface of the plate wall portion that is to be attached to the casing, and is configured to come into contact with a peripheral edge of the casing through hole,
wherein a portion of the connection member that protrudes on a first surface side corresponding to the first surface of the plate wall portion includes a circuit-side connection portion,
the circuit-side connection portion is detachably connectable to the circuit member,
the circuit-side connection portion of the connection member is inserted into the casing through hole from outside the casing and connected to the circuit member, and the sealing member of the wall plate portion comes into contact with the peripheral edge of the casing through hole from outside of the casing,
the in-vehicle electrical component circuit unit further comprises a base plate portion configured to be placed onto and fixed to the holding body,
the base plate portion is made of a material with higher heat conductivity than the holding body,
the base plate portion is provided with a support leg portion that protrudes downward from the base plate portion, and
a protruding height of the support leg portion is set to adjust a height position of the plate wall portion relative to the casing through hole.

2. The in-vehicle electrical component circuit unit according to claim 1,
wherein the connection member of the connector is constituted by a bus bar,
the circuit-side connection portion is provided at a protruding end portion on the first surface side of the plate wall portion, and
an external connection portion is provided at a protruding end portion of the plate wall portion on a second surface side corresponding to a second surface of the plate wall portion that is opposite to the first surface.

3. The in-vehicle electrical component circuit unit according to claim 2,
wherein the connector includes a hood portion that is provided on the second surface of the plate wall portion and protrudes toward the second surface side while surrounding the external connection portion.

4. The in-vehicle electrical component circuit unit according to claim 1,
wherein the circuit-side connection portion is configured to be bolted to the connection member, and
a bolt insertion hole provided in the circuit-side connection portion has an elongated shape that is elongated in a direction in which the plate wall portion is attached to the casing.

5. The in-vehicle electrical component circuit unit according to claim 1,
wherein a wiring component is provided in a region covered by the support leg portion and a bottom wall of the casing.

6. (canceled)
